(19) United States
(12) Patent Application Publication
(10) Pub. No.: US 2012/0218029 A1
(43) Pub. Date: Aug. 30, 2012

(54) TOUCH SWITCH

(75) Inventors: Norihiko FURUTA, Komaki-shi (JP); Motoyuki FURUTA, Gifu-shi (JP); Atsushi MURAMATSU, Komaki-shi, Aichi-ken (JP); Tomonori HAYAKAWA, Komaki-shi (JP)

(73) Assignee: TOKAI RUBBER INDUSTRIES, LTD., Aichi-ken (JP)

(21) Appl. No.: 13/403,086

(22) Filed: Feb. 23, 2012

(30) Foreign Application Priority Data
Feb. 24, 2011 (JP) 2011-037908
Feb. 25, 2011 (JP) 2011-039360

(51) Int. Cl. H03K 17/96

(52) U.S. Cl. 327/517

(57) ABSTRACT

A touch switch including: a conductive member for which voltage is applied from a plurality of locations for detecting presence or absence of a touch and a touch position on the conductive member of a conductor to be detected based on an electrical conduction status of the conductive member; and a detection-level changing mechanism for changing a detection level of the electrical conduction status of the conductive member due to the touch of the conductor on the conductive member. The presence or absence of the touch and the touch position on the conductive member of the conductor is detected if the detection level meets a predetermined condition.

### INCORPORATED BY REFERENCE

The disclosures of Japanese Patent Application Nos. 2011-037908 filed on Feb. 24, 2011 and 2011-039360 filed on Feb. 25, 2011, including the specifications, drawings and abstracts are incorporated herein by reference in its entirety.

### BACKGROUND OF THE INVENTION

1. Field of the Invention

The present invention relates to a touch switch for detecting the touch of a user's finger or the like, and particularly relates to a touch switch that can prevent misoperation.

2. Description of the Related Art

In general, vehicles, buildings or the like are equipped with switches which are correlated to specified operations (functions) such as switching on and off indoor lights, opening and closing of electrically powered windows or the like. These switches can be selectively operated to execute the target operation as necessary.

In recent years, instead of mechanical switches that mechanically detect a user operation, touch switches (touch panels) that electrically detect the touch of the user on a screen have rapidly become widespread, and studies are being done for applying this to operation of the air conditioner and the like in automobiles, for example. This touch switch is an item that detects electrical changes when the user's finger which is a conductor touches a button displayed on a flat screen, as shown in Unexamined Patent Publication No. 2009-75656 (Patent Documents 1) or the like, for example.

However, with Patent Document 1, since the touch switch button is displayed on a sufficiently large screen for the size of the finger, there was the risk of the user inadvertently making contact while doing other work or the like and causing an unintended operation.

### SUMMARY OF THE INVENTION

The present invention has been developed considering the circumstances described above as the background, and it is one object of the present invention to provide a touch switch of a novel constitution which is able to prevent misoperation by inadvertent touching without blocking the user's intended operation.

Specifically, a first mode of the present invention provides a touch switch comprising: a conductive member for which voltage is applied from a plurality of locations for detecting presence or absence of a touch and a touch position on the conductive member of a conductor to be detected based on an electrical conduction status of the conductive member; and a detection-level changing mechanism for changing a detection level of the electrical conduction status of the conductive member due to the touch of the conductor on the conductive member, wherein the presence or absence of the touch and the touch position on the conductive member of the conductor is detected if the detection level meets a predetermined condition.

In the touch switch according to the present mode, the detection-level changing mechanism is provided and the detection of the presence or absence of the touch and the touch position on the conductive member of the conductor is detected if the detection level meets a predetermined condition. By arranging the detection-level changing mechanism such that the detection level of the electrical conduction status of the conductive member will meet the predetermined condition, if the user intentionally or correctly operates the touch switch, it is possible to detect only the case when the user correctly operates the touch switch, and to disregard the case when the user mistakenly contacts the touch switch since the detection level does not meet the predetermined condition. The predetermined condition of the detection level of the electrical conduction status of the conductive member may be determined, for example, whether or not the value of a voltmeter disposed between the power supply and the conductive member meets a threshold value, or utilizing another value sensed from any point on the electrical circuit.

A second mode of the present invention provides the touch switch according to the first mode, wherein the detection-level changing mechanism comprises a conductive touch confirmation member to which a grounding side electrode of a power supply for applying voltage to the conductive member is connected, and the detection level meets the predetermined condition under a state of electrical conduction of the conductive member in relation to the touch confirmation member.

With a touch switch of a constitution according to this mode, when the conductor to be detected has touched the conductive member, the conductive member and the touch confirmation member are made electrically conductive. Thus, the detection level will meet the predetermined condition, whereby, the presence or absence of the touch and the touch position on the conductive member are detected, and a preset operation is executed according to the input to the touch switch. Meanwhile, since the power supply and the grounding side electrode are not made electrically conductive in a state when the conductive member and the touch confirmation member are not electrically conductive. Thus, the detection level will not meet the predetermined condition, whereby, even when the conductor to be detected touches the conductive member, the presence or absence of the touch and the touch position on the conductive member are not detected. Accordingly, even if there is inadvertent contact of the conductive member unintentionally, the touch switch does not accept this, preventing misoperation.

In other words, with the touch switch of the present mode, cases when the user intentionally operates the touch switch and cases when the user mistakenly contacts the touch switch are determined by whether or not there is electrical conduction of the conductive member and the touch confirmation member, and only the operations intended by the user are selectively executed. Namely, the detection-level changing mechanism can be constituted by the conductive touch confirmation member.

A third mode of the present invention provides the touch switch according to the first or the second mode, wherein the conductive member and the touch confirmation member are provided on both surfaces of an insulation layer having electrical insulating properties, respectively.

With the third mode, since the conductive member and the touch confirmation member are provided on both surfaces of the insulation layer, the conductive member and the touch confirmation member are arranged adjacent in a state with electrical conduction prevented by the insulation layer. In this way, when the conductive member and the touch confirmation member are made electrically conductive by arranging the conductive member and the touch confirmation member at near positions, it is possible to minimize the electrical resistance at the electrically conductive part between the conductive member and the touch confirmation member. As a result, it is possible to set a high level for the detection signals (current), improving the detection precision, the detection result reliability and the like.

Furthermore, since the conductive member and the touch confirmation member are arranged at near positions and these can easily be made electrically conductive by grasping them using hands or the like, it is easy to perform operations while making the conductive member and the touch confirmation member be electrically conductive. Also, because the conductive member and the touch confirmation member are arranged at both sides sandwiching the insulation layer, it is difficult to have electrical conduction of the conductive member and the touch confirmation member, and touching of the conductive member and the conductor to be detected occur simultaneously without doing so intentionally, making it possible to establish both ease of operation and effective prevention of misoperation.

A fourth mode of the present invention provides the touch switch according to the third mode, wherein the insulation layer is constituted by a handle portion projecting from a wall part and extending facing opposite the wall part, and one of the conductive member and the touch confirmation member is provided on one surface of the handle portion that faces opposite the wall part, while another of the conductive member and the touch confirmation member is provided on another surface of the handle portion that is remote from the wall part.

With the fourth mode, the conductive member and the touch confirmation member are provided on both surfaces of the insulation layer in the form of the handle portion, the conductive member and the touch confirmation member become electrically conductive by grasping the handle portion, and also, the touching part of the finger on the conductive member is used as the conductor to be detected, and input to the switch is performed by touching with the finger. By selectively accepting operations in a state for which grasping of the handle portion does not easily occur unintentionally, it is possible to prevent misoperation in cases of accidental contact.

Also, since one of the conductive member or the touch confirmation member is arranged facing opposite the wall part, and it is necessary to put a finger or the like as the conductor between the wall part and the handle portion to operate the touch switch, inadvertent touching is more effectively prevented.

A fifth mode of the present invention provides the touch switch according to the fourth mode, wherein the handle portion is an automobile handle portion including at least one of a door armrest, an inside door handle and an assist grip.

With the fifth mode, with an automobile, it is possible to control things such as the window opening and closing operation, opening and closing of the door locks, turning on and off as well as airflow adjustment of the air conditioner, turning on and off of the headlights and the like without misoperation due to inadvertent contact. Also, by providing a touch switch on the automobile handle portion which is grasped in the hand, it is possible to do operation easily while grasping the automobile handle portion with one hand.

A sixth mode of the present invention provides the touch switch according to any one of the second through fifth modes, wherein at least one of the conductive member and the touch confirmation member is formed of a conductive resin.

As shown with the sixth mode, if the conductive member and the touch confirmation member are formed using conductive resin, it is possible to increase the degree of freedom for the shape using molding. Therefore, for example even when a three dimensional shape such as a door handle shape or the like is required, it is possible to easily mold the conductive member and the touch confirmation member to a specified shape.

A seventh mode of the present invention provides the touch switch according to any one of the second through sixth modes, wherein at least one of the conductive member and the touch confirmation member is formed of a conductive coating material.

With the seventh mode, by coating the surface of a member made of resin or the like with excellent moldability using a conductive coating material, it is possible to easily form a three dimensional conductive member or touch confirmation member.

A eighth mode of the present invention provides the touch switch according to the first mode, wherein the conductive member includes an operating surface, the detection-level changing mechanism comprises a divider projection member formed of an insulating material and provided on a part of the operating surface in order to divide the operating surface, and the detection level meets the predetermined condition if the conductor touches on the operating surface without intervening the divider projection member.

With the touch switch of a constitution according to the eighth mode, an unintended touch on the operating surface of the conductor is prevented by the divider projection member formed of the insulating material. Thus, the detection level will not meet the predetermined condition, whereby, erroneous input to the operating surface by an unintended touch is avoided. On the other hand, during an intentional use, the conductor touches on the operating surface without intervening the divider projection member. Thus, the detection level will not meet the predetermined condition, whereby, it is possible to selectively accept only operations intended by the user, and to execute operations corresponding to the operation.

A ninth mode of the present invention provides the touch switch according to any one of the first through eighth modes, wherein an AC voltage is applied to the conductive member, and a dielectric layer is provided on a surface of the conductive member for detecting the presence or absence of the touch and the touch position on the conductive member of the conductor via the dielectric layer.

With the ninth mode, since the conductor to be detected indirectly touches the conductive member via the dielectric layer, wear and degradation of the conductive member are prevented, and durability is improved. Also, by applying AC voltage, even when a dielectric layer is interposed between the conductive member and the conductor to be detected, current essentially flows between the conductive member and the conductor to be detected based on electrostatic capacity, and whether or not there is a touch and the touch position are effectively detected.

A tenth mode of the present invention provides the touch switch according to any one of the first through eighth modes, wherein a DC voltage is applied to the conductive member for detecting the presence or absence of a direct touch and the touch position on the conductive member of the conductor.

With the tenth mode, by having the conductor to be detected directly touch the conductive member, it is possible to use DC voltage, making it possible to use a simple constitution for the power supply.

An eleventh mode of the present invention provides the touch switch according to any one of the first through tenth modes, wherein a displacement volume and a displacement direction of the touch position on the conductive member of the conductor is identified by continuously detecting the touch position.

With the eleventh mode, since the movement of the conductor to be detected on the conductive member is detected, by correlating an operation with changes in the touch position rather than just whether or not there is a touch and the touched position, it is possible to realize more operations with one touch switch.

With the present invention, touching of the conductor to be detected on the conductive member is detected only when the detection level meets a predetermined condition. Therefore, when the user intentionally operates the touch switch, the input is accepted, and an operation is executed according to that operation, but meanwhile, when the user unintentionally contacts the touch switch, that input is not accepted, and it is possible to prevent execution of an operation by mistake.

### BRIEF DESCRIPTION OF THE DRAWINGS

The foregoing and/or other objects, features and advantages of the invention will become more apparent from the following description of a preferred embodiment with reference to the accompanying drawings in which like reference numerals designate like elements and wherein:

FIG. 1 is a vertical cross sectional diagram showing a touch switch as a first embodiment of the present invention, taken along line 1-1 of FIG. 2;

FIG. 2 is a cross sectional view taken along line 2-2 of FIG. 1;

FIG. 3 is a view for explaining the touch position specification method with the touch switch shown in FIG. 1;

FIG. 4 is a circuit diagram showing an electric circuit constituted during the operation of the touch switch shown in FIG. 1;

FIG. 5 is a key part enlarged view showing the switch unit of the touch switch shown in FIG. 1, and is a view in the direction of arrow A of FIG. 1;

FIG. 6 is a vertical cross sectional diagram showing an assist grip equipped with a touch switch as a second embodiment of the present invention, taken along line 6-6 of FIG. 7;

FIG. 7 is a cross sectional view taken along line 7-7 of FIG. 6.

FIG. 8 is a view for explaining the touch position specification method with the touch switch shown in FIG. 6;

FIG. 9 is a view showing the state with a touch switch as a third embodiment of the present invention provided on the door arm rest of an automobile;

FIG. 10 is a vertical cross sectional diagram showing the touch switch of FIG. 9, taken along line 10-10 of FIG. 11;

FIG. 11 is a cross sectional view taken along line 11-11 of FIG. 10;

FIG. 12 is a view for explaining the detection mechanism for the touch switch shown in FIG. 10;

FIG. 13 is a circuit diagram showing an electric circuit during operation of the touch switch shown in FIG. 12;

FIG. 14 is a view showing a touch switch as another embodiment of the present invention;

FIG. 15 is a view showing a touch switch as yet another embodiment of the present invention; and

FIG. 16 is a view showing a touch switch as even yet another embodiment of the present invention.

### DETAILED DESCRIPTION OF PREFERRED EMBODIMENTS

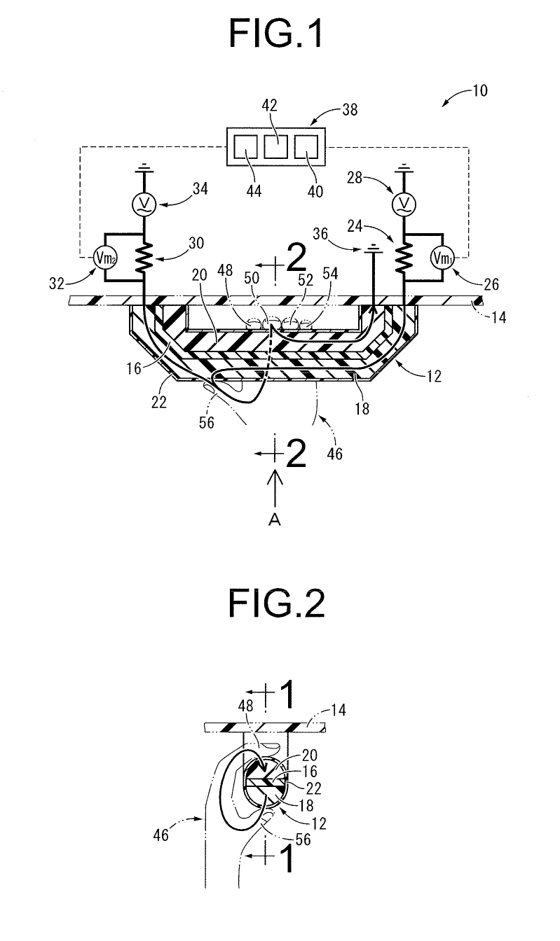

FIG. 1 and FIG. 2 show a touch switch 10 as the first embodiment of the present invention. This touch switch 10 is provided on the assist grip 12 as an automobile handle portion. The assist grip 12 is a grip for the passenger to grasp to support his body and maintain posture when the automobile is running, and is attached to the automobile roof side part 14. Note that with the following explanation, as a rule, the up-down direction means the up-down direction in FIG. 1 which is the vertical up-down direction, and the front-back direction means the left-right direction in FIG. 1 which is the vehicle front-back direction.

In more detail, the assist grip 12 has a constitution for which the conductive member 18 is provided on one surface of the insulation layer 16, and also a touch confirmation member 20 is provided on the other surface. The insulation layer 16 is formed of a rubber material, synthetic resin material or the like, has electrical insulation properties, has both end parts projecting downward roughly orthogonally to the roof side part 14, and also has a door handle shape that curves and for which the middle part is separated a specified distance in relation to the roof side part 14 and extends in the front-back direction. In this way, with this embodiment, the roof side part 14 is used as the wall part that supports the assist grip 12.

The conductive member 18 is provided on one surface of the insulation layer 16. The conductive member 18 is formed of an electrically conductive resin material for which a conductive filler such as carbon black or the like is mixed in a synthetic resin material. The conductive member 18 is superimposed so as to cover the front-back outside surface and the entire bottom surface of the insulation layer 16, and is adhered to the insulation layer 16. In other words, the conductive member 18 is provided on the surface of the insulation layer 16 that is remote from the roof side part 14, and is arranged to the side of the car interior space.

Also, the touch confirmation member 20 is provided on the other surface of the insulation layer 16. The touch confirmation member 20, the same as with the conductive member 18, is formed of a conductive resin material for which a conductive filler such as carbon black or the like is mixed in a synthetic resin material. The touch confirmation member 20 is superimposed so as to cover the front-back direction inside surface and entire top surface of the insulation layer 16, and is adhered to the insulation layer 16. In other words, the touch confirmation member 20 is provided on the surface of the insulation layer 16 that faces opposite the roof side part 14. The resistance value of the touch confirmation member 20 is preferably made sufficiently small to a negligible level compared to the resistance value of the conductive member 18 by adjusting the volume of conductive filler mixed in the synthetic resin material or the like.

Also, with this embodiment, the insulation layer 16, the conductive member 18, and the touch confirmation member 20 are covered by a dielectric layer 22. The dielectric layer 22 is formed by an elastomer material, synthetic resin material or the like having dielectric properties, is thin-walled, and is provided so as to cover roughly the entire surface of the insulation layer 16, the conductive member 18, and the touch confirmation member 20 surfaces (excluding the adhesion surface to the roof side part 14).

The assist grip 12 is attached and supported at both end parts thereof on the roof side part 14 of the automobile. The attachment constitution to the roof side part 14 is not particularly limited, and it is also possible to adhere using gluing or welding means or the like, and to have this axially supported to be able to slide on the roof side part 14.

Also, as shown in FIG. 1, a first detection resistor 24 is electrically connected to the end part of the front side of the conductive member 18, and also, a first voltmeter 26 for measuring the voltage value Vm₁ of the first detection resistor 24 is provided. Furthermore, a first AC power supply 28 is connected to the first detection resistor 24 and the conductive member 18, and AC voltage is applied from the first AC power supply 28 to the first detection resistor 24 and the conductive member 18.

Meanwhile, a second detection resistor 30 is electrically connected to the end part of the back side of the conductive member 18, and also, a second voltmeter 32 for measuring the voltage value Vm₂ of the second detection resistor 30 is provided. Furthermore, the second AC power supply 34 is connected to the second detection resistor 30 and the conductive member 18, and AC voltage is applied from the second AC power supply 34 to the second detection resistor 30 and the conductive member 18. The first detection resistor 24 and the second detection resistor 30 have mutually the same resistance value r, and by measuring the first voltmeter 26 measured value Vm₁ and the second voltmeter 32 measured value Vm₂, the size of the current that flows to the first and second detection resistors 24 and 30 is measured. Furthermore, since the first AC power supply 28 and the second AC power supply 34 apply AC voltage of the same phase and the same electric potential, with the conductive member 18 and the touch confirmation member 20 in an insulated state, a steady-state current does not flow to the conductive member 18 and the first and second detection resistors 24 and 30. Therefore, with the conductive member 18 and the touch confirmation member 20 in an insulated state, the measured values of the first and second voltmeters 26 and 32 both become 0 (Vm₁=Vm₂=0).

Also, a grounding side electrode 36 of the first and second AC power supply 28, 34 is electrically connected to the end part of the front side of the touch confirmation member 20, and the electrical potential of the grounding side electrode 36 is 0 with grounding.

Furthermore, the measured value of the first voltmeter 26 and the measured value of the second voltmeter 32 are both sent to a processing device 38 as electrical signals. The processing device 38 has, for example, conduction confirmation means 40 for determining whether or not there is a touch based on the measured values, operation specifying means 42 for specifying the touch position when the conduction confirmation means 40 detects a touch, and control signal output means 44 for executing a specified operation on a vehicle device according to the type of operation specified by the operation specifying means 42.

With a touch switch 10 having this kind of constitution, a presence or absence of the touch and the touch position on the conductive member 18 of a conductor to be detected are detected based on the state of electrical conduction at the conductive member 18. Specifically, as shown by the double dot-dash line in FIG. 1 and FIG. 2, the passenger grasps the assist grip 12 with his hand 46, and while touching the touch confirmation member 20 using at least one of the index finger (second finger) 48, the middle finger (third finger) 50, the ring finger (fourth finger) 52, and the pinky finger (fifth finger) 54, by having the thumb (first finger) 56 as the conductor to be detected touch the conductive member 18, the conductive state of the conductive member 18 changes, and the presence or absence of a touch and the touch position of the thumb 56 on the conductive member 18 is specified.

In more detail, since the human hand 46 is a conductor, as shown in FIG. 1, when the passenger grasps the assist grip 12 with the hand 46, the conductive member 18 and the touch confirmation member 20 are electrically connected through the hand 46. By doing this, currents I₁ and I₂ flow to the conductive member 18 and the first and second detection resistors 24 and 30, and the voltage values Vm₁ and Vm₂ are measured by the first and second voltmeters 26 and 32 according to the current that flows to the first and second detection resistors 24 and 30. Then, the conduction confirmation means 40 of the processing device 38 detects a touch of the thumb 56 (conductor to be detected) on the conductive member 18 when each of the measured values Vm₁ and Vm₂ of the first and second voltmeters 26 and 32 is a specified threshold value or greater. Note that in FIG. 1, the path in which the current flows through the assist grip 12 and the hand 46 is shown by an arrow.

The conduction confirmation means 40 detects touching of the thumb 56 on the conductive member 18 with the conductive member 18 and the touch confirmation member 20 in a conductive state. This conduction confirmation means 40 for example determines whether or not the measurement values of the first and second voltmeters 26 and 32 are a preset threshold value or greater, and when it is determined that the measurement value is a threshold value or greater, conduction of the conductive member 18 and the touch confirmation member 20 is confirmed. Specifically, even in a case when the hand 46 contacts only the conductive member 18 and there is no conduction for the conductive member 18 and the touch confirmation member 20, the conductive member 18 is grounded through the user's body and current can flow to the first and second detection resistors 24 and 30. However, with this kind of grounding mode, the path from the conductive member 18 to the grounding point is long, and since that path is the human body which is a resistor, the electrical resistance value is high, and the current that flows to the first and second detection resistors 24 and 30 becomes smaller. As a result, the measurement value is lower than the aforementioned threshold value, and touching of the conductive member 18 is not detected. Meanwhile, when the conductive member 18 and the touch confirmation member 20 are made conductive by the hand 46, the conductive member 18 is grounded by the touch confirmation member 20 that has a sufficiently lower resistance value than the human body and an electric line. By doing this, the current that flows to the first and second detection resistors 24 and 30 becomes the threshold value or greater, and since conduction of the conductive member 18 and the touch confirmation member 20 is confirmed by the conduction confirmation means 40, touching of the thumb 56 on the conductive member 18 is detected. That is, the touch confirmation member 20 to which the grounding side electrode 36 of the first and second AC power supply 28, 34 is connected will provide a function as a detection-level changing mechanism for changing a detection level of the electrical conductive status of the conductive member 18 due to the touch of the thumb 56 (conductor) on the conductive member 18.

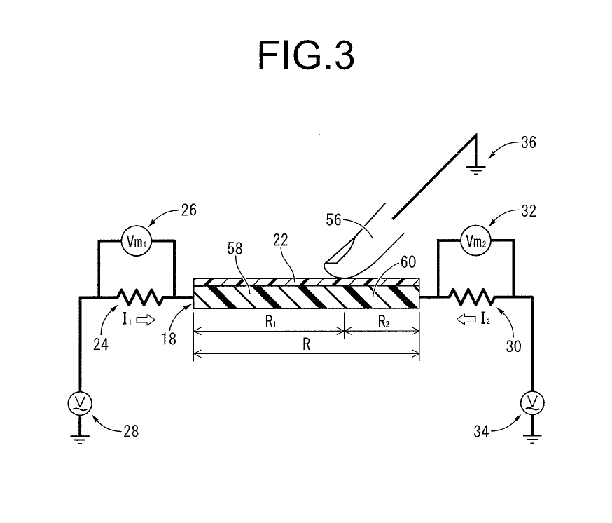

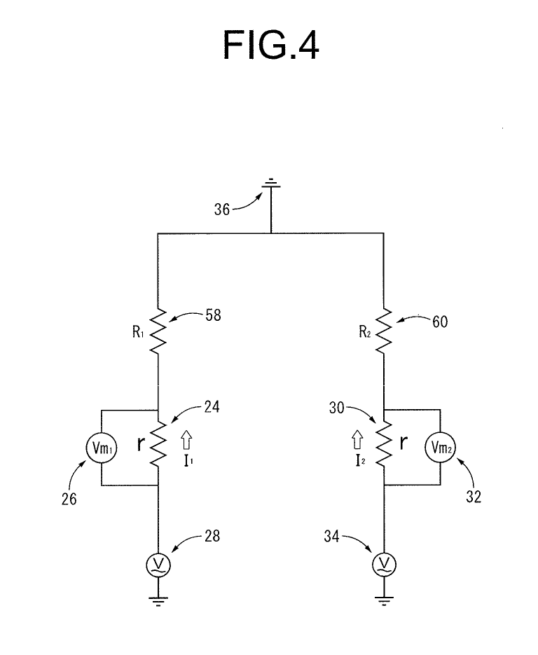

When electrical conduction between the conductive member 18 and the touch confirmation member 20 is confirmed by the conduction confirmation means 40, the detection level of the electrical conduction status of the conductive member 18 due to the touch of the thumb 56 (conductor) on the conductive member 18 will meet a predetermined condition. Therefore, the operation specifying means 42 of the processing device 38 specifies the touch position of the thumb 56 on the conductive member 18 based on the measurement values of the first and second voltmeters 26 and 32. Specifically, as shown in FIG. 3, when the thumb 56 touches the middle part of the conductive member 18 for which the overall resistance value is R, the conductive member 18 as a resistor is substantially divided into a first resistor 58 (resistance value R₁) from one end (in FIG. 3, the left end) to the touch position of the thumb 56, and a second resistor 60 (resistance value R₂) from the other end (in FIG. 3, the right end) to the touch position of the thumb 56. Since the ratio of the resistance value R₁ of the first resistor 58 and the resistance value R₂ of the second resistor 60 is roughly the same as the ratio of the distance from one end of the conductive member 18 to the touch position of the thumb 56 and the distance from the other end of the conductive member 18 to the touch position of the thumb 56, the touch position of the thumb 56 on the conductive member 18 is specified by finding the ratio of R₁ and R₂. FIG. 4 shows an electrical circuit diagram of the conductive member 18 and the touch confirmation member 20 in a state made conductive by the hand 46.

With this embodiment, the surface of the conductive member 18 and the touch confirmation member 20 is covered by the dielectric layer 22, and the hand 46 indirectly touches the conductive member 18 and the touch confirmation member 20 via the dielectric layer 22. In this way, by having the hand 46 face opposite the conductive member 18 and the touch confirmation member 20, a capacitor with the hand 46 (first finger 56) and the conductive member 18 as electrodes is constituted, and a capacitor with the hand 46 (second to fifth fingers 48, 50, 52, 54) and the touch confirmation member 20 as electrodes is constituted. Since AC voltage is applied to the conductive member 18 from the first and second AC power supplies 28 and 34, current flows between the hand 46 and the conductive member 18, and the hand 46 and the touch confirmation member 20. In other words, the touch switch 10 of this embodiment is a capacitive coupling type, and an indirect touch of the thumb 56 on the conductive member 18 via the dielectric layer 22 is made to be detected.

Also, the measurement of the voltage values is repeatedly performed by the first and second voltmeters 26 and 32 at specified time intervals, and the changes in the touch position of the thumb 56 on the conductive member 18 is continuously detected by the operation specifying means 42. Thus, when the thumb 56 is moved while touching the surface of the conductive member 18, the thumb 56 displacement direction, displacement volume, and displacement speed are specified.

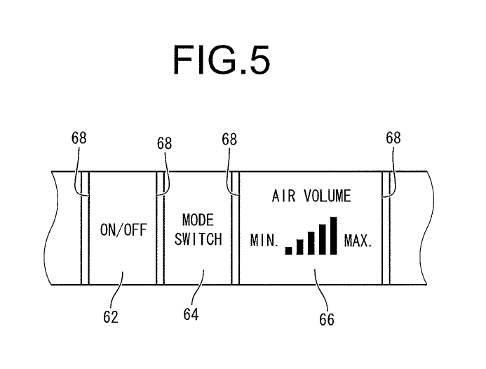

When the type of operation specified by the touch position of the thumb 56 on the conductive member 18 is determined by the operation specifying means 42, the control signal output means 44 of the processing device 38 outputs a control signal to the automobile device and performs an operation according to the operation on the device. The device controlled by the operation of the touch switch 10 is not particularly limited, but for example the air conditioner of an automobile can be controlled by operation of the touch switch 10. In specific terms, for example, by performing an operation with touching of the thumb 56 on a first switch unit 62 of the conductive member 18 shown in FIG. 5 while grasping the assist grip 12 and making the conductive member 18 and the touch confirmation member 20 conductive by the hand 46, on/off switching signals are output to the air conditioner from the control signal output means 44. Furthermore, by performing an operation with touching of the thumb 56 on a second switch unit 64 of the conductive member 18 shown in FIG. 5 while making the conductive member 18 and the touch confirmation member 20 conductive, switching signals for the working mode (heating, air conditioning, or air outlet) of the air conditioner are output from the control signal output means 44. Yet further, by performing an operation with stroking the thumb 56 on the third switch unit 66 of the conductive member 18 in the front-back direction (in FIG. 5, the left-right direction) while making the conductive member 18 and the touch confirmation member 20 conductive, air volume adjustment signals are output to the air conditioner from the control signal output means 44. At the time of this air volume adjustment, an air volume increase operation and decrease operation is determined by the displacement direction of the thumb 56 on the conductive member 18, and also, the air volume change volume is set by the displacement volume of the thumb 56 on the conductive member 18, and furthermore, the air volume change volume per unit of time (change speed) is set by the displacement speed of the thumb 56 on the conductive member 18. As shown in FIG. 5, it is also possible to have the first through third switch units 62, 64, and 66 be divided by a recessed groove 68 or the like, and have the position of the first through third switch units 62, 64, and 66 be specified by the sense of touch.

As shown by the above however, the correlation of the touch switch 10 operation and the operation of an air conditioner or the like is merely an example, without being limited, and for example it is also possible to use this for car window opening and closing, audio device operation, car interior light operation or the like.

With the touch switch 10 constituted according to this embodiment, when the touch operation is performed, it is possible to execute an operation according to the touch position of the thumb 56 on the conductive member 18 and the change volume and change direction thereof and the like using a very simple method of grasping the assist grip 12 with the hand 46 and touching the conductive member 18 with the thumb 56.

Meanwhile, with the touch switch 10, since it is necessary to perform the touch operation while grasping the handle shaped assist grip 12 and making the conductive member 18 and the touch confirmation member 20 conductive, even when the conductive member 18 is unintentionally contacted by accident, the touch operation is not accepted, and misoperation due to unintended touching is prevented. In particular, since the touch confirmation member 20 is provided inside the assist grip 12, and the part grasped by the hand 46 faces opposite the roof side part 14, it is difficult for unintentional contact of both the conductive member 18 and the touch confirmation member 20 to occur, and misoperation is effectively prevented.

Also, with the touch switch 10, the conduction confirmation means 40 is provided, and the touch of the conductor to be detected (thumb 56) on the conductive member 18 is detected only in a state of conduction for the conductive member 18 and the touch confirmation member 20. Because of that, intended operation and unintended touching are distinguished with good precision by the conduction confirmation means 40, preventing misoperation.

Also, since the conductive member 18 and the touch confirmation member 20 are provided at both surfaces of the insulation layer 16 and arranged at near positions, by making the conductive member 18 and the touch confirmation member 20 conductive, compared to when the hand 46 contacts only the conductive member 18, the electrical resistance is suppressed and a larger current flows to the first and second detection resistors 24 and 30. Because of that, it is possible to distinguish with high precision intentional touching and unintentional touching, making it possible to prevent misoperation due to inadvertent touching.

Also, the conductive member 18 and the touch confirmation member 20 are formed of an electrically conductive resin. This makes it possible to increase the degree of freedom of the shape of the conductive member 18 and the touch confirmation member 20. It is also possible to easily deal with three dimensional shapes such as that of the assist grip 12.

Also, it is possible to detect not only the touch position of the thumb 56 on the conductive member 18, but also the changes in the touch position (movement). This makes it possible to execute specified operations corresponding to the touch position movement volume and touch position movement direction and the like. Therefore, it becomes possible to execute more operations with one touch switch 10, and it is also possible to perform not only on/off control, but also sound volume and air volume control and the like using an easy to understand, simple operation.

Also, the touch switch 10 of this embodiment is a capacitive coupling type, and the dielectric layer 22 is provided on the surface of the conductive member 18 and the touch confirmation member 20. Thus, there is no direct touching of the hand 46 on the conductive member 18 and the touch confirmation member 20 and durability is improved.

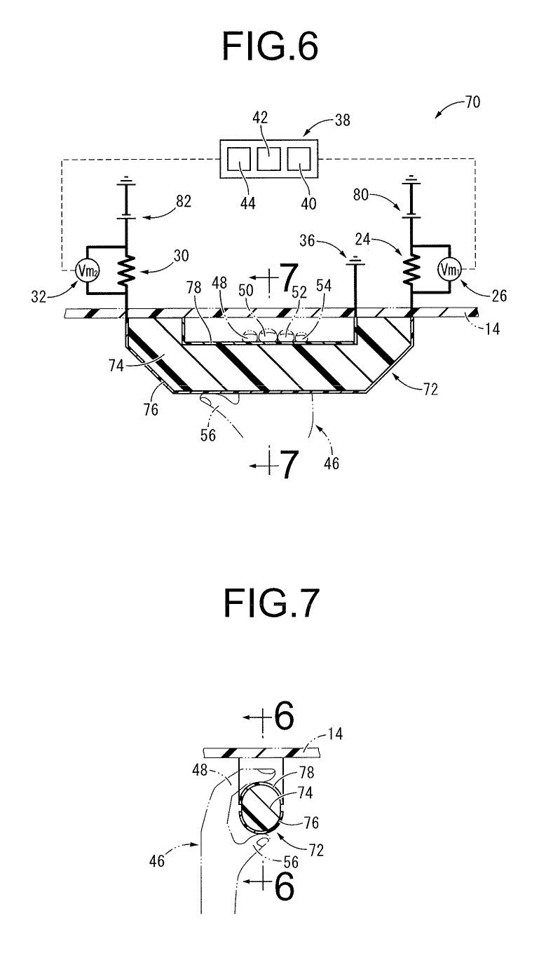

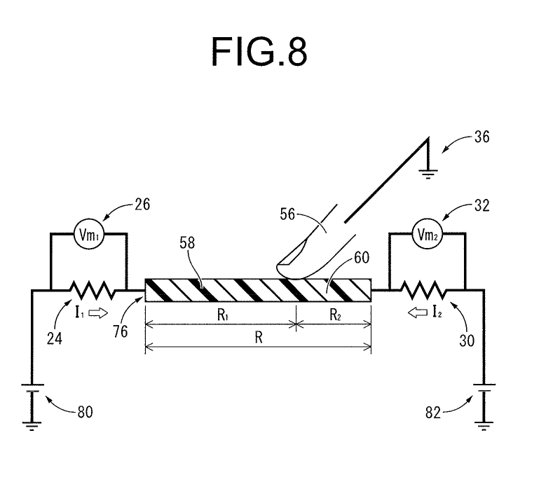

FIG. 6 and FIG. 7 show a touch switch 70 as a second embodiment of the present invention. The touch switch 70 has the assist grip 72 provided as an automobile handle portion. In the following explanation, the same code numbers are given in the drawings for essentially the same members and sites as those of the first embodiment, and an explanation of these is omitted.

The assist grip 72 has an insulating member 74 as the insulation layer, a conductive member 76 adhered to one surface of the insulating member 74, and a touch confirmation member 78 adhered to the other surface of the insulating member 74. The insulating member 74 is a member presenting a handle shape, and is used as an insulator formed using a synthetic resin material or the like.

Also, the conductive member 76 is adhered to one surface of the insulating member 74. The conductive member 76 is formed by having a rubber type conductive coating material, for which carbon black is mixed as the conductive filler in an item for which an organic solvent is added to a prepared rubber compound and a printing solvent is further added, be formed by printing in a specified shape on one surface of the insulating member 74 using a method such as screen printing, inkjet printing, flexo printing, gravure printing, pad printing, lithography or the like.

On this conductive member 76, a first DC power supply 80 is attached to one end part attached to the roof side part 14, and a specified DC voltage is applied. Furthermore, at the other end part attached to the roof side part 14 of the conductive member 76, a second DC power supply 82 is attached, and a DC voltage of the same potential as that of the first DC power supply 80 is applied. By doing this, in a state without touching of the hand 46, current does not flow to the conductive member 76. The first and second detection resistors 24 and 30 and the first and second voltmeters 26 and 32 provided between the first and second DC power supplies 80 and 82 and the conductive member 76 are the same as those of the first embodiment, so an explanation of these is omitted.

Also, the touch confirmation member 78 is adhered on the other surface of the insulating member 74. The touch confirmation member 78, the same as with the conductive member 76, is formed by printing a conductive coating material on the other surface of the insulating member 74 in a specified shape, and by providing this separated from the conductive member 76, there is electrical insulation in relation to the conductive member 76. The forming material for the conductive member 76 and the touch confirmation member 78 is not particularly limited, and it is possible to use various known items as long as they are coating materials having conductivity.

With the touch switch 70 with this kind of constitution as well, the same as with the touch switch 10 of the first embodiment, simultaneous with grasping the assist grip 72 using the hand 46 and making the conductive member 76 and the touch confirmation member 78 conductive, by touching a specified site of the conductive member 76 with the thumb 56, the operation corresponding to the touch position of the thumb 56 on the conductive member 76 is executed. As a result, misoperation due to unintended touching is avoided.

Also, with the touch switch 70 of this embodiment, the conductive member 76 and the touch confirmation member 78 are exposed to the outside, and as shown in FIG. 7, the hand 46 is made to directly touch the conductive member 76 and the touch confirmation member 78. Then, whether or not there is a direct touch and the touch position of the thumb 56 on the conductive member 76 are detected. Because of that, it is possible to use the first and second DC power supplies 80 and 82 for applying the DC voltage, and to simplify the power supply. As will be apparent from this, the touch switch 70 of this embodiment is the resistive coupling type.

By omitting the dielectric layer 22 with the constitution of the first embodiment, and also applying DC voltage to the conductive member 18 with the first and second DC power supplies 80 and 82 instead of the first and second AC power supplies 28 and 34, it is possible to make a resistive coupling type touch switch. Similarly, with the constitution of the second embodiment, by having the surface of the conductive member 76 and the touch confirmation member 78 be covered by the dielectric layer 22, and also, by applying an AC voltage to the conductive member 76 with the first and second AC power supplies 28 and 34 instead of the first and second DC power supplies 80 and 82, it is possible to have the touch switch be the capacitive coupling type.

We gave a detailed description of the embodiment of the present invention, but the present invention is not limited to those specific notations.

For example, with this embodiment, the conductive member 18 and the touch confirmation member 20 were arranged in near positions sandwiching the insulation layer 16, but the conductive member and the touch confirmation member can also be arranged in separated individual positions as long as they are electrically insulated from each other. In more specific terms, it is possible for both the conductive member and the touch confirmation member to have a flat plane shape, for the conductive member to be arranged on the door of an automobile, and also, for the touch confirmation member to be arranged on the roof of the automobile, and to have the touch switch accept operations by, while touching the touch confirmation member with one hand, touching the conductive member with the other hand.

The conduction of the conductive member and the touch confirmation member is not limited to being conduction through the human body by touch of the hand, but for example can also be conduction of the conductive member and the touch confirmation member via a member for conduction with an electrical resistance smaller than that of the human body. Furthermore, the conductor to be detected which specifies the touch position is not limited to being a person's thumb, but can also be a separate site of the human body such as an index finger or the like, or can be a separate member such as a pen shaped touch member or the like.

It is also possible to have voltage applied to the conductive member from a plurality of locations, and this is not limited to necessarily being two locations. Specifically, with the aforementioned embodiments, the touch position of the thumb 56 on the conductive member 18 was specified one dimensionally in the front-back direction of a vehicle, but for example it is also possible to have voltage applied from four locations on the conductive member, and rather than being in the vehicle front-back direction on the conductive member, can have the touch position specified also in the vehicle left-right direction or the vehicle top-bottom direction. In other words, by applying voltage to four locations, it is possible to two dimensionally detect the touch position and its changes on the conductive member.

Also, the forming material of the conductive member and the touch confirmation member is not limited to being the conductive synthetic resin or conductive coating material shown in the aforementioned embodiments, but it is also possible to use a metal material or the like such as copper since this works as long as the electrical conductivity is sufficiently large. Furthermore, it is also possible to use the conductive resin shown in the first embodiment for one of the conductive member or the touch confirmation member, and to use the conductive coating material shown in the second embodiment for the other of the conductive member or the touch confirmation member, and it is not necessary to form the conductive member and the touch confirmation member using the same material.

Also, as long as the insulation layer is interposed between the conductive member and the touch confirmation member, and has an electrical insulating function, there is no particular limitation on the shape, and for example it is also possible to use differently shaped insulating members as insulation layers.

Also, with the aforementioned embodiments, the touch switch 10 was provided on the assist grip 12 of the automobile, but the touch switch can for example also be used as an operating device that switches the door locked state and unlocked state provided in the door arm rest of an automobile, and can also be an operating device for car window opening and closing provided on the inside door handle. The touch switch of the present invention is also not necessarily used only for automobiles, but can also be used for household door handles, lighting switches or the like.

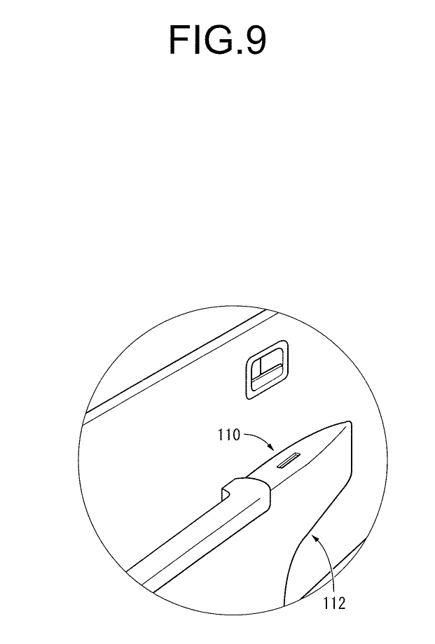

Referring next to FIG. 9, there is shown a touch switch 110 as a third embodiment of the present invention. The touch switch 110 is provided on the top surface of an arm rest 112 provided on the door part of an automobile, and is used as the input interface for opening and closing the car windows.

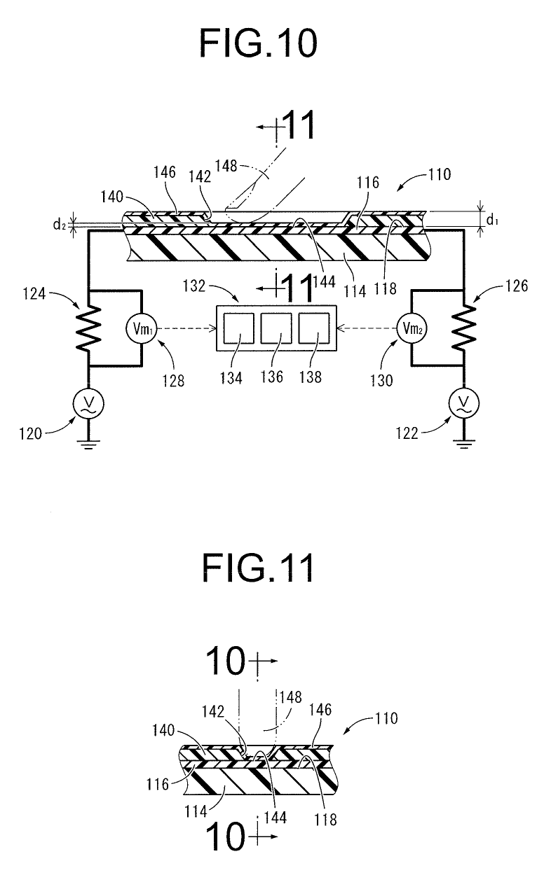

In more detail, as shown in FIG. 10 and FIG. 11, the touch switch 110 has a substrate 114 formed of an insulating material and a conductive member 116 superimposed on its surface. The substrate 114 is formed by a material having electrical insulating properties such as a synthetic resin or the like. In the drawing, the substrate 114 is shown with a flat plane shape, but the shape is not particularly limited to this.

The conductive member 116 is formed of a conductive material having high electrical conductivity, and with this embodiment, is formed using a conductive resin material for which a conductive filler such as carbon black or the like is mixed with a synthetic resin material. Then, the conductive member 116 is superimposed on the top surface of the substrate 114 and adhered. Alternatively, the conductive member 116 can also be formed by preparing a rubber type conductive coating material, for which carbon black is mixed as the conductive filler in an item wherein an organic solvent is added to a prepared rubber compound and a printing solvent is further added, and by printing in a specified shape on the top surface of the substrate 114 using a method such as screen printing, inkjet printing, flexo printing, gravure printing, pad printing, lithography or the like. It is also possible to form the conductive member 116 using a conductor such as a metal plate or the like.

The conductive member 116 is superimposed at its bottom surface on the top surface of the substrate 114 and adhered. The top surface of the conductive member 116 is used as an operating surface 118 and the touch of a conductor to be detected described later is detected. The operating surface 118 of this embodiment is a flat surface with almost no irregularities, but the shape of the operating surface is not particularly restricted, and for example can be tilted in relation to a horizontal plane or vertical plane, and can be bent and recessed in a concave form or the like.

At one end of the conductive member 116, a first AC power supply 120 is connected, and AC voltage is applied to one end of the conductive member 116 from the first AC power supply 120. Meanwhile, at the other end of the conductive member 116, a second AC power supply 122 is connected, and AC voltage is applied to the other end of the conductive member 116 from the second AC power supply 122. Same phase and same potential voltage is applied from two locations to the conductive member 116 by these first and second AC power supplies 120 and 122, and current does not flow to the conductive member 116 in the non-touching state of a finger 148 described later.

A first detection resistor 124 is connected at one end of the conductive member 116. The first detection resistor 124 is arranged on the connection path of the one end of the conductive member 116 and the first AC power supply 120, and is electrically connected with the conductive member 116 and the first AC power supply 120. Meanwhile, a second detection resistor 126 is connected at the other end of the conductive member 116. The second detection resistor 126 is arranged on the connection path of the other end of the conductive member 116 and the second AC power supply 122, and is electrically connected with the conductive member 116 and the second AC power supply 122. The first and second detection resistors 124 and 126 have the same resistance value (r).

A first voltmeter 128 for measuring the voltage applied to the first detection resistor 124 is provided, and also a second voltmeter 130 for measuring the voltage applied to the second detection resistor 126 is provided. Then, by confirming the electrical conduction status at the conductive member 116 based on the measured value of the first and second voltmeters 128 and 130, things such as whether or not there is a touch and the touch position on the conductive member 116 by the conductor to be detected described later is detected.

Furthermore, the first and second voltmeters 128 and 130 are connected to the processing device 132 either with a wire or wirelessly. The processing device 132 has touch confirmation means 134 for determining whether or not there is a touch on the conductive member 116 by the conductor to be detected described later based on the measurement results of the first and second voltmeters 128 and 130, operation specifying means 136 for specifying the touch position and a change in the touch position (operation) when a touch is confirmed on the conductive member 116 of the conductor to be detected by the touch confirmation means 134, and control signal output means 138 for outputting to a car window opening and closing device (not illustrated) control signals according to the operation specified by the operation specifying means 136.

Also, a divider projection member 140 is provided on the operating surface 118 of the conductive member 116. The divider projection member 140 is formed with a material having electrical insulation properties, is superimposed on the operating surface 118 of the conductive member 116, and is provided so as to project upward from the operating surface 118. Furthermore, the divider projection member 140 has a sufficiently large thickness dimension compared to an dielectric layer 146 described later, and the distance d₁ from the operating surface 118 of the conductive member 116 to the surface of the dielectric layer 146 at the part provided by the divider projection member 140 is sufficiently large compared to the distance d₂ from the operating surface 118 of the conductive member 116 to the surface of the dielectric layer 146 at the part not provided by the divider projection member 140 (the slit 142 forming part described later) (d₁>d₂).

A slit 142 is formed penetrating the divider projection member 140. This slit 142 is a rectangular hole, and it penetrates the divider projection member 140 in the vertical direction while also gradually contracting as it goes downward. To say this another way, the divider projection member 140 of this embodiment has an annular plate shape having a rectangular center hole, and its center hole is the slit 142. Then, the operating surface 118 of the conductive member 116 is divided by the divider projection member 140, and the part exposed through the slit 142 which is not covered by the divider projection member 140 at the operating surface 118 is used as the detection surface 144, and by inserting the finger 148 into the slit 142, it is possible to touch the detection surface 144 without the finger 148 going via the divider projection member 140. The width dimension of the slit 142 is not particularly restricted, but it is preferable to be of a size for which the finger 148 can be inserted and also that other human body parts such as the palm of the hand, arm or the like cannot be inserted, and for example, is suitably 1 cm or greater and 3 cm or less at the bottom opening part which is the narrowest width.

The top surface of the divider projection member 140 and the detection surface 144 of the conductive member 116 are covered by the dielectric layer 146. The dielectric layer 146 is a thin-walled layer formed by a synthetic resin material or the like having dielectric properties, and is suitably equipped with resistance to wear and erosion or the like due to the atmosphere. By having this kind of dielectric layer 146 provided, the finger 148 touches the detection surface 144 indirectly via the dielectric layer 146. The dielectric layer 146 can be provided only on the detection surface 144 of the conductive member 116, and does not absolutely have to be provided extending to above the divider projection member 140. Also, the dielectric layer 146 can be formed as a single unit with the divider projection member 140, and in that case, the thick-walled part by the difference in the thickness direction functions as the divider projection member, and also the thin-walled part functions as the dielectric layer.

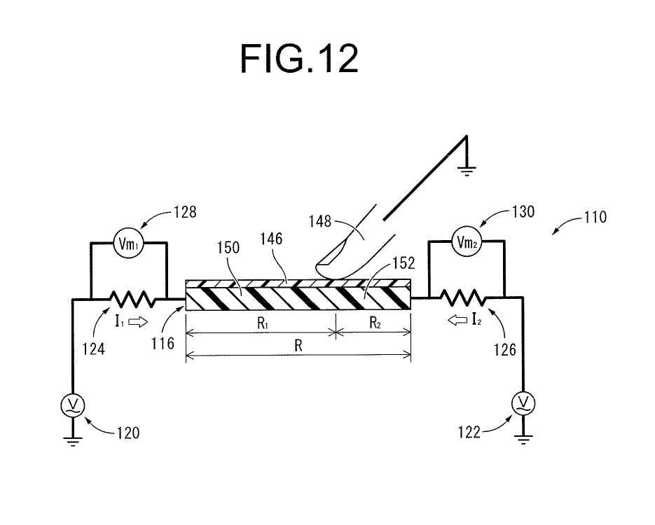

Then, as shown in FIG. 12, when the finger 148 is inserted in the slit 142 and touches the detection surface 144 of the conductive member 116 via the dielectric layer 146, the conductive member 116 is grounded through the human body including the finger 148, so currents I₁ and I₂ flow to the conductive member 116 and the first and second detection resistors 124 and 126. With this embodiment, the dielectric layer 146 is provided between the finger 148 and the conductive member 116, but since AC voltage is applied to the conductive member 116, a capacitor is constituted with the conductive member 116 and the finger 148 as electrodes, and current flows between the conductive member 116 and the finger 148. In other words, the touch switch 110 of this embodiment is of the capacitive coupling type.

When the currents I₁ and I₂ flow to the first and second detection resistors 124 and 126, voltage values Vm₁ and Vm₂ are measured according to the current flowing to the first and second detection resistors 124 and 126 with the first and second voltmeters 128 and 130. Then, the touch confirmation means 134 of the processing device 132 detects touching of the finger 148 (conductor to be detected) on the conductive member 116 when each of the measured values Vm₁ and Vm₂ of the first and second voltmeters 128 and 130 is of a specified numerical value or greater. The touch confirmation means 134 is an item that determines whether or not the measured value of the first and second voltmeters 128 and 130 for example are a preset threshold value or greater, and when determined that the measured value is the threshold value or greater, detects touching of the finger 148 on the detection surface 144 of the conductive member 116.

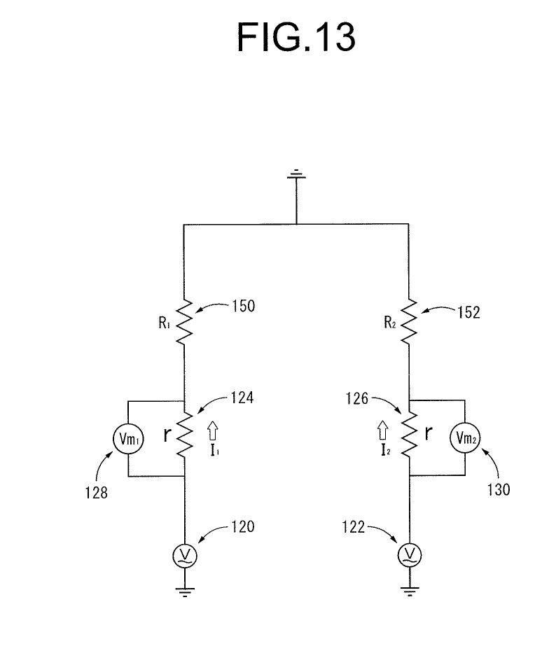

Then, when a touch of the finger 148 is detected on the detection surface 144 of the conductive member 116, the operation specifying means 136 of the processing device 132 specifies the contact position on the detection surface 144 of the finger 148 based on the measured values of the first and second voltmeters 128 and 130. Specifically, as shown in FIG. 12, when the finger 148 touches the middle part of the conductive member 116 for which the overall resistance value is set as R, the conductive member 116 as the resistor is substantially divided into a first resistor 150 (resistance value R₁) from one end (in FIG. 12, the left end) up to the touch position of the finger 148 and a second resistor 152 (resistance value R₂) from the other end (in FIG. 12, the right end) up to the touch position of the finger 148. The ratio of the resistance value R₁ of the first resistor 150 and the resistance value R₂ of the second resistor 152 and the ratio of the distance from one end of the conductive member 116 up to the touch position of the finger 148 and the distance from the other end of the conductive member 116 up to the touch position of the finger 148 are roughly the same, so the touch position of the finger 148 on the conductive member 116 is specified by finding the ratio of R₁ and R₂. FIG. 13 shows the state of the finger 148 touching the conductive member 116 as an electric circuit diagram.

Measurement of the voltage value by the first and second voltmeters 128 and 130 is repeated at specified time intervals, and changes in the touch position of the finger 148 on the conductive member 116 are continuously detected by the operation specifying means 136. By doing this, when the finger 148 is moved while touching the surface of the conductive member 116 (detection surface 144), the finger 148 displacement direction and displacement volume are specified.

When the touch position of the finger 148 or movement while touching is detected by the operation specifying means 136, the control signal output means 138 of the processing device 132 outputs to a vehicle device control signals according to the touch position of the finger 148 on the detection surface 144 or the movement volume and movement direction or the like while touching the detection surface 144. The devices controlled by the operation of the touch switch 110 are not particularly limited, but with this embodiment, for example, a car window opening and closing device (not illustrated) is made to be controlled, and the opening and closing operation of the car window is executed according to the input operation to the touch switch 110. With this embodiment, by moving the finger 148 in the lengthwise direction of the slit 142 while touching the detection surface 144, the opening operation and the closing operation are distinguished according to the movement direction (in FIG. 10, leftward or rightward), and also, the car window opening and closing volume is set according to the movement volume, and this is output as control signals to the car window opening and closing device from the control signal output means 138.

Meanwhile, when a human body including the finger 148 touches the top surface of the divider projection member 140, the same as when the finger 148 is inserted in the slit 142, a capacitor is constituted with the conductive member 116 and the finger 148 as electrodes, but the distance between the conductive member 116 and the finger 148 is via the divider projection member 140, so is greater than when the finger 148 touches the detection surface 144. Because of that, compared to when the finger 148 touches the detection surface 144, the electrical capacity is smaller, and there is less current flowing to the first and second detection resistors 124 and 126. As a result, the measured values of the first and second voltmeters 128 and 130 are less than the preset threshold value, and it is determined by the touch confirmation means 134 that the finger 148 is not touching the conductive member 116. From the above, with the touch switch 110, only touches through the slit 142 by the finger 148 on the detection surface 144 of the conductive member 116 are selectively detected.

Accordingly, with the touch switch 110, accidental opening and closing operation of the car window by unintended touching of the operating surface 118 is prevented. Specifically, by the divider projection member 140 being provided on the operating surface 118, unintended touching of the operating surface 118 is prevented by the divider projection member 140, and misoperation is prevented. Particularly with this embodiment, inadvertent touching is effectively avoided because the divider projection member 140 is provided so as to restrict the exposure of the operating surface 118 to within the narrow width slit 142 to the degree that the finger 148 can be inserted.

Meanwhile, when intentionally doing the car window opening and closing operation, when the finger 148 is put into the always open slit 142, by sliding the finger 148 while touching the operating surface 118 (detection surface 144), it is possible to do the operation easily without requiring extra work such as opening an unintended touch prevention cover or the like. Because the detection surface 144 is provided on the bottom surface of the part that is a concave shape using the slit 142, by searching for the top side opening part of the slit 142 using the sense of touch of the fingertips, it is possible to know the position of the detection surface 144 without confirming by sight.

Furthermore, with the capacitive coupling type touch switch 110 according to this embodiment, the distance between the electrodes of the capacitor constituted with the finger 148 and the conductive member 116 as electrodes will be changed by whether or not there is a divider projection member 140, thereby changing the size or level of the flowing current by the touch of the finger 148. This makes it possible to distinguish presence or absence of a touch on the operating part. That is, by providing the divider projection member 140 formed by an insulating material on the operating surface 118, it is possible to accurately distinguish whether or not there is a touch on the detection surface 144 using a simple constitution. As will be understood from the above-description, the divider projection member 140 provided on the operating surface 118 of the conductive member 116 will provide a function as a detection-level changing mechanism for changing a detection level of the electrical conductive status of the conductive member 116 due to the touch of the finger 148 (conductor) on the conductive member 116, and the detection level of the electrical conductive status of the conductive member 116 will satisfy the predetermined condition if the finger 148 is touched on the detection surface 144 on the operating surface 118 without intervening the divider projection member 140.

Also, if the conductive member 116 is formed using a conductive resin, the molding degree of freedom becomes great by molding the conductive member 116 itself, making it possible to easily obtain the target shape conductive member 116. Meanwhile, if the conductive member 116 is formed using a conductive coating material, the conductive member 116 is formed along the shape of the substrate 114. Thus, by forming the substrate 114 using a typical synthetic resin or the like with a high degree of freedom for the shape, it is possible to easily obtain the target shape conductive member 116.

Since the detection surface 144 is covered by the dielectric layer 146, degradation and wear of the conductive member 116 by the finger 148 repeatedly touching and sliding is prevented, improving the durability of the conductive member 116. Also, since an AC voltage is applied to the conductive member 116 from the first and second AC power supplies 120 and 122, touching of the finger 148 via the dielectric layer 146 on the conductive member 116 is effectively detected based on the electrostatic capacity.

This embodiments illustrates an example of a car window opening and closing by sliding of the finger 148 on the detection surface 144 of the touch switch 110, but for example it is also possible to have the car window do the opening operation by the finger 148 touching one end part of the lengthwise direction of the detection surface 144, and to have the car window do the closing operation by the finger 148 touching the other end part of the lengthwise direction of the detection surface 144. In other words, the touch switch can be an item that detects sliding of the conductor to be detected on the operating surface, and output control signals according to the sliding direction and volume, or it can also be an item that detects the touch position of the conductor to be detected on the operating screen, and output control signals according to the touch position.

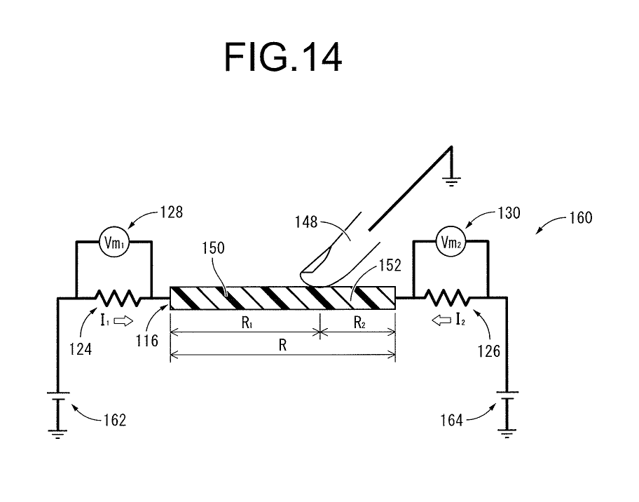

While the third embodiment of the present invention has been described in detail, the present invention is not limited to those specific notations. For example, with the aforementioned embodiment, a capacitive coupling type touch switch 110 was shown, but the application range of the present invention is not limited to a capacitive coupling type touch switch, and for example can also be applied for example to a resistive coupling type touch switch. In specific terms, as shown in FIG. 14, a resistive coupling type touch switch 160 has a constitution for which the dielectric layer 146 is removed from the touch switch 110 shown in the aforementioned embodiment, and also uses first and second DC power supplies 162 and 164 in place of the first and second AC power supplies 120 and 122, and has DC voltage of the same electric potential applied to the conductive member 116. With this kind of resistive coupling type touch switch 160, the finger 148 is inserted in the slit 142 and directly touches the conductive member 116, and by the conductive member 116 being grounded through the human body, current flows to the conductive member 116, and the touch and touch position of the finger 148 on the conductive member 116 are detected. Meanwhile, when the finger 148 touches the conductive member 116 via the divider projection member 140, since a DC voltage is applied, current does not flow because of insulation by the divider projection member 140, and a touch is not detected. By working in these ways, with the resistive coupling type touch switch 160 as well, whether or not there is a touch by the conductor to be detected (finger 148) on the conductive member 116 is detected. Since power supplies 162 and 164 to apply DC voltage can be used, it is possible to use simple items for the power supply circuits. Note that the touch position detection method is the same as for the capacitive coupling type touch switch 110 shown with the aforementioned embodiment, so we will omit an explanation here. Also, essentially the same members and same sites as those of the aforementioned embodiment are given the same code numbers in the drawings and an explanation of these is omitted.

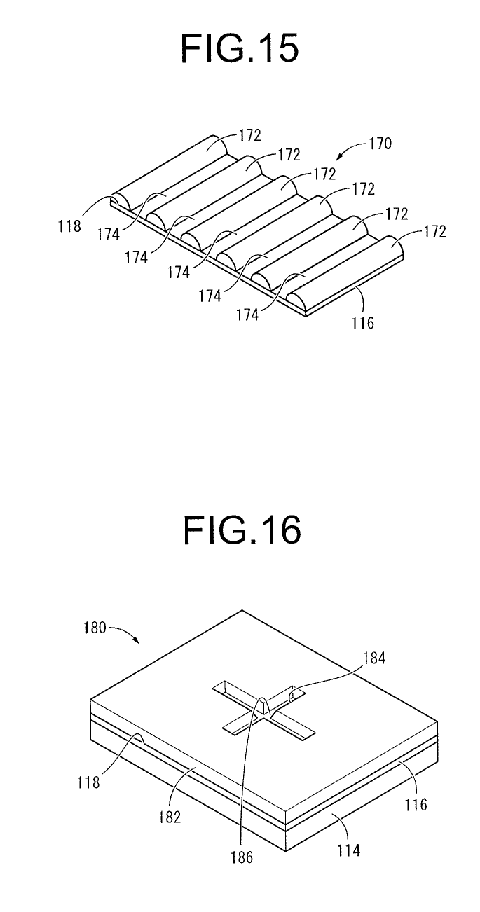

Also, the shape of the divider projection member is not particularly restricted, but for example it is also possible to use a divider projection member 172 such as of a touch switch 170 shown in FIG. 15. Specifically, with the touch switch 170, a plurality of divider projection members 172 having a linear convex shape are arranged in parallel at specified intervals on the operating surface 118 of the conductive member 116, and detection surfaces 174 for detecting the touch of the finger 148 are respectively provided between adjacent divider projection members 172, 172. With the touch switch 170 having this kind of constitution as well, unintended touch by the finger 148 on the operating surface 118 is prevented by the divider projection members 172. Furthermore, with the touch switch 170 of this embodiment, the operating surface 118 is divided by the divider projection member 172 and a plurality of detection surfaces 174 are provided, so it is possible to make different operations corresponding to which of the detection surfaces 174 is touched. Also, since the operating surface 118 is divided by the divider projection member 172 and divided into a plurality of detection surfaces 174, it is possible to perform the target operation easily using the sense of touch without requiring visual observation. By making the shape of the divider projection members 172 different or the like, it is possible to more easily grasp the position of the detection surface 174 by sense of touch. Note that in FIG. 15 and FIG. 16, illustrations of the power supply, resistors for detection, voltmeters and the like are omitted.

Furthermore, in addition to the plate shape or convex shape, the divider projection member can also use a convex shape such a hemispheric shape or the like, for example. In other words, the convex shape for division is not particularly restricted in terms of shape as long as it is formed using an electrically insulating material and prevents unintended touching of the operating surface 118 by projecting from the operating surface 118.

Yet further, as a divider projection member, for example a divider projection member 182 such as of a touch switch 180 shown in FIG. 16 can be used. Specifically, with the touch switch 180, a divider projection member 182 is equipped with a window part 184 that presents a cross shape with the vertical direction view with two slits combined so as to be orthogonal to each other, and the part exposed through the window part 184 on the operating surface 118 of the conductive member 116 is used as the detection surface 186. Furthermore, voltage is applied from four locations on the conductive member 116, and input to the detection surface 186 is made to be detected in two mutually orthogonal directions. If the divider projection member 182 having this kind of window part 184 is used in combination with application of voltage from four locations on the conductive member 116, it is possible to detect input to the detection surface 186 in two mutually orthogonal directions. As is clear from the above, the voltage applied to the conductive member 116 is not necessarily limited to being from two locations, and for example it is possible to specify touch positions in two dimensions (on a flat plane) with application from four locations as with the aforementioned touch switch 180. There is no particular limit on the shape of the window part, and it is also possible to use a T shape or a shape like the character “ [symbol] ” or the like.

Also, the conductor to be detected that touches the detection surface 144 does not absolutely have to be the finger 148, and it is also possible to have the conductive state of the conductive member 116 be changed by the touch of the conductor to be detected, and have the touch of the conductor to be detected on the conductive member 116 be detected. In specific terms, for example, it is possible to use a touch pen or the like formed with a conductive material as the conductor to be detected.

As the device controlled by the operation of the touch switch, this is not limited to be a car window opening and closing device, but can also be for example an item for which the control device of an air conditioner, an audio system, a door lock opening and closing device, or a car interior light is controlled by the operation of the touch switch.

Furthermore, with the embodiment noted above, the touch switch 110 was provided on the arm rest 112 of the door part of an automobile, but the touch switch can also for example be a switch for turning on or off a car interior light provided on the car interior side wall surface of an automobile roof, can be provided on an instrument panel, or can be an input interface for operating an air conditioner or audio system. Yet further, the touch switch of the present invention does not absolutely have to be used only for an automobile, but for example can also be used for a household lighting switch or the like.

What is claimed is:

1. A touch switch comprising:
a conductive member for which voltage is applied from a plurality of locations for detecting presence or absence of a touch and a touch position on the conductive member of a conductor to be detected based on an electrical conduction status of the conductive member; and
a detection-level changing mechanism for changing a detection level of the electrical conduction status of the conductive member due to the touch of the conductor on the conductive member,
wherein the presence or absence of the touch and the touch position on the conductive member of the conductor is detected if the detection level meets a predetermined condition.

2. The touch switch according to claim 1, wherein the detection-level changing mechanism comprises a conductive touch confirmation member to which a grounding side electrode of a power supply for applying voltage to the conductive member is connected, and the detection level meets the predetermined condition under a state of electrical conduction of the conductive member in relation to the touch confirmation member.

3. The touch switch according to claim 1, wherein the conductive member and the touch confirmation member are provided on both surfaces of an insulation layer having electrical insulating properties, respectively.

4. The touch switch according to claim 3, wherein the insulation layer is constituted by a handle portion projecting from a wall part and extending facing opposite the wall part, and one of the conductive member and the touch confirmation member is provided on one surface of the handle portion that faces opposite the wall part, while another of the conductive member and the touch confirmation member is provided on another surface of the handle portion that is remote from the wall part.

5. The touch switch according to claim 4, wherein the handle portion is an automobile handle portion including at least one of a door armrest, an inside door handle and an assist grip.

6. The touch switch according to claim 2, wherein at least one of the conductive member and the touch confirmation member is formed of a conductive resin.

7. The touch switch according to claim 2, wherein at least one of the conductive member and the touch confirmation member is formed of a conductive coating material.

8. The touch switch according to claim 1, wherein the conductive member includes an operating surface, the detection-level changing mechanism comprises a divider projection member formed of an insulating material and provided on a part of the operating surface in order to divide the operating surface, and the detection level meets the predetermined condition if the conductor touches on the operating surface without intervening the divider projection member.

9. The touch switch according to claim 1, wherein an AC voltage is applied to the conductive member, and a dielectric layer is provided on a surface of the conductive member for detecting the presence or absence of the touch and the touch position on the conductive member of the conductor via the dielectric layer.

10. The touch switch according to claim 1, wherein a DC voltage is applied to the conductive member for detecting the presence or absence of a direct touch and the touch position on the conductive member of the conductor.

11. The touch switch according to claim 1, wherein a displacement volume and a displacement direction of the touch position on the conductive member of the conductor is identified by continuously detecting the touch position.
